(19) United States
(12) Patent Application Publication
(10) Pub. No.: US 2026/0255982 A1
(43) Pub. Date: Aug. 27, 2026

(54) METHOD FOR DEPOSITING METAL CONDUCTIVE LAYER ON GLASS SUBSTRATE

(71) Applicant: Skytech Inc., Hsinchu County (TW)

(72) Inventors: YAO-SYUAN CHENG, Hsinchu County (TW); KUO-JU LIU, Hsinchu County (TW); TA-HAO KUO, Hsinchu County (TW); CHING-LIANG YI, Hsinchu County (TW)

(21) Appl. No.: 19/199,346

(22) Filed: May 5, 2025

(30) Foreign Application Priority Data
Feb. 21, 2025 (TW) 114106610

(51) Int. Cl. H10W 70/05; H10W 70/66; H10W 70/692

(52) U.S. Cl. CPC H10W 70/095; H10W 70/097; H10W 70/66; H10W 70/692

(57) ABSTRACT

This disclosure is a method for depositing a metal conductive layer on a glass substrate. Firstly, a glass substrate is cleaned, and then a titanium metal thin film is formed on the surface of the glass substrate. The titanium metal thin film is performed a surface treatment by using a reactive plasma to form an intermediate layer, wherein the intermediate layer includes a titanium oxide thin film, a titanium nitride thin film, a titanium fluoride thin film, or a titanium chloride thin film. A titanium metal conductive layer is formed on the intermediate layer of the glass substrate. The titanium metal conductive layer is connected to the glass substrate through the intermediate layer, which can increase the adhesion between the titanium metal conductive layer and the glass substrate, and is beneficial to improve the yield and reliability of subsequent packaging processes.

### CROSS-REFERENCE TO RELATED APPLICATIONS

This non-provisional application claims priority claim under 35 U.S.C. §119(a) on Taiwan Patent Application No. 114106610 filed February 21, 2025, the entire contents of which are incorporated herein by reference.

### TECHNICAL FIELD

The disclosure is a method for depositing a metal conductive layer on a glass substrate, which can increase the adhesion between a titanium metal conductive layer and the glass substrate, and is beneficial to improve the yield and reliability of subsequent packaging processes.

### BACKGROUND

Semiconductor packaging typically involves the process of mounting small, semiconductor dies onto a packaging substrate, followed by the encapsulation of the dies and substrate within a package housing. This assembly enables the dies to be electrically connected to external circuitry via the packaging substrate, facilitating their operational functionality.

Specifically, the packaging substrate serves to provide structural support and protection for the semiconductor die, and prevents the die from being damaged during transportation and use. The conductive layer disposed on the packaging substrate can be used to connect the electrodes of the die with external circuits, so as to realize the transmission of electrical signals between the die and external circuits. In addition, the packaging substrate can also be used to transfer the heat generated during the operation of the die to the outside to prevent the die from overheating.

Conventionally, organic materials are widely employed for packaging substrate fabrication, offering benefits such as cost-effectiveness and ease of production. Compared with substrates made of organic materials, glass substrates play an increasingly important role in the field of semiconductor packaging due to their excellent properties, such as high heat resistance, high flatness, low coefficient of thermal expansion, high transparency, low dielectric constant, and high mechanical strength. These properties render them particularly advantageous for applications in 5G communications, high-performance computing chipsets, and electric vehicle technologies.

However, glass substrates present challenges including increased cost, heightened processing complexity, and reduced interfacial adhesion with metals. For instance, in the case of depositing a titanium metal conductive film onto a glass substrate surface, the adhesive strength between the titanium film and the glass substrate is limited to approximately 0.05 kgf, which may cause the titanium metal conductive layer to peel off the surface of the glass substrate, thereby affecting the yield and reliability of subsequent packaging processes.

### SUMMARY

In order to solve the problems described in the prior art, this invention provides a method for depositing a metal conductive layer on a glass substrate. This method can increase the adhesion between the metal conductive layer and the glass substrate, and is beneficial to improve the yield and reliability of subsequent packaging processes.

It is an objective of the invention to provide a method for depositing a metal conductive layer on a glass substrate, which forms an intermediate layer on a surface of the glass substrate, and then forms a titanium metal conductive layer on the intermediate layer. By incorporating the intermediate layer, the adhesion between the titanium metal conductive layer and the glass substrate can be improved, and the probability of separation between the titanium metal conductive layer and the glass substrate can be reduced.

It is an objective of the invention to provide a method for depositing a metal conductive layer on a glass substrate. A titanium metal thin film is formed on the surface of the glass substrate, and surface treatment is performed on the titanium metal thin film through reactive plasma. Thereby, the titanium metal thin film will be transformed into an intermediate layer, which facilitates the subsequent deposition of a titanium metal conductive layer onto the glass substrate.

It is an objective of the invention to provide a method for depositing a metal conductive layer on a glass substrate. A reactive gas is introduced into a deposition chamber during the titanium deposition process on the surface of the glass substrate, to form an intermediate layer on the surface of the glass substrate. Subsequently, a titanium metal conductive layer is deposited onto the intermediate layer, which enhances the interfacial adhesion between the titanium metal conductive layer and the glass substrate.

To achieve the foregoing objectives, this disclosure provides a method for depositing a metal conductive layer on a glass substrate, comprising: performing a cleaning process on a glass substrate; depositing a titanium metal thin film on a surface of the glass substrate; performing a surface treatment on the titanium metal thin film located on the surface of the glass substrate through a reactive plasma to transform the titanium metal thin film into an intermediate layer, wherein the reactive plasma includes an oxygen plasma, a nitrogen plasma, a fluorine plasma, or a chlorine plasma, and the intermediate layer includes a titanium oxide thin film, a titanium nitride thin film, a titanium fluoride thin film, or a titanium chloride thin film; and depositing a titanium metal conductive layer on a surface of the intermediate layer.

This disclosure provides another method for depositing a metal conductive layer on a glass substrate, comprising: performing a cleaning process on a glass substrate; transporting the glass substrate into a deposition chamber; inputting a reactive gas into the deposition chamber, and performing a thin film deposition on the glass substrate to form an intermediate layer on a surface of the glass substrate, wherein the reactive gas includes an oxygen, a nitrogen, a fluorine, or a chlorine, and the intermediate layer includes a titanium oxide thin film, a titanium nitride thin film, a titanium fluoride thin film, or a titanium chloride thin film; and depositing a titanium metal conductive layer on a surface of the intermediate layer.

The method for depositing a metal conductive layer on a glass substrate according to the invention has the following advantages: it can improve the adhesion between the titanium metal conductive layer and the glass substrate, and is beneficial to improve the yield and reliability of subsequent packaging processes.

### BRIEF DESCRIPTION OF THE DRAWINGS

FIG. 1 is a flow chart of a method for depositing a metal conductive layer on a glass substrate according to an embodiment of the invention.

FIG. 2 is a schematic diagram of a glass substrate with a titanium metal thin according to an embodiment the invention.

FIG. 3 is a schematic diagram of a glass substrate with a titanium metal conductive layer according to an embodiment the invention.

FIG. 4 is a flow chart of the method for depositing the metal conductive layer on the glass substrate according to another embodiment of the invention.

FIG. 5 is a schematic diagram of a deposition chamber for forming the titanium metal conductive layer on the glass substrate according to an embodiment of the invention.

### DETAILED DESCRIPTION

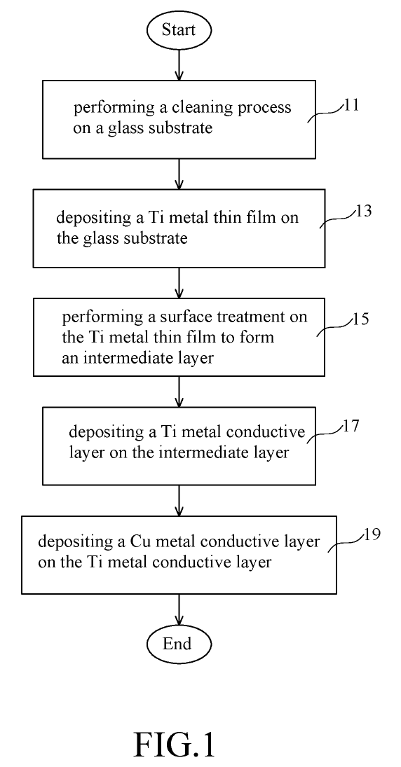

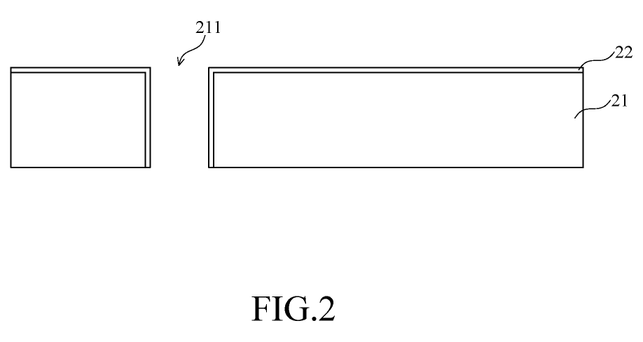

FIG. 1 is a flow chart of a method for depositing a metal conductive layer on a glass substrate according to an embodiment of the invention. In conjunction with FIG. 2, the glass substrate 21 is subjected to a cleaning process, as shown in step 11.

In one embodiment of the invention, the glass substrate 21 may include silicon dioxide, aluminosilicate, alkali-aluminosilicate, borosilicate, alkali-borosilicate, aluminoborosilicate, alkali-aluminoborosilicate, soda-lime, etc. For example, the glass substrate 21 includes 70% or 75% or more of silicon dioxide, and the thickness of the glass substrate 21 may be less than or equal to 3mm

In practical applications, the glass substrate 21 may be first subjected to wet cleaning, for example, cleaning the glass substrate 21 with acetone to remove grease or other organic contaminants on the surface of the glass substrate, and then cleaning the glass substrate 21 with methanol to dissolve the acetone remaining on the surface of the glass substrate 21, and finally cleaning the glass substrate 21 with deionized water to remove the organic solvent remaining on the surface of the glass substrate 21.

The above method of cleaning the glass substrate 21 and using acetone and methanol to clean the glass substrate 21 is only an embodiment of the invention and is not a limitation of the scope of the invention.

Following the wet cleaning of the glass substrate 21, a subsequent heating process can be employed to eliminate residual moisture from the substrate surface. In operational practice, prior to the thermal treatment of the glass substrate 21, a high-pressure nitrogen gas gun may be utilized to expel the majority of surface moisture.

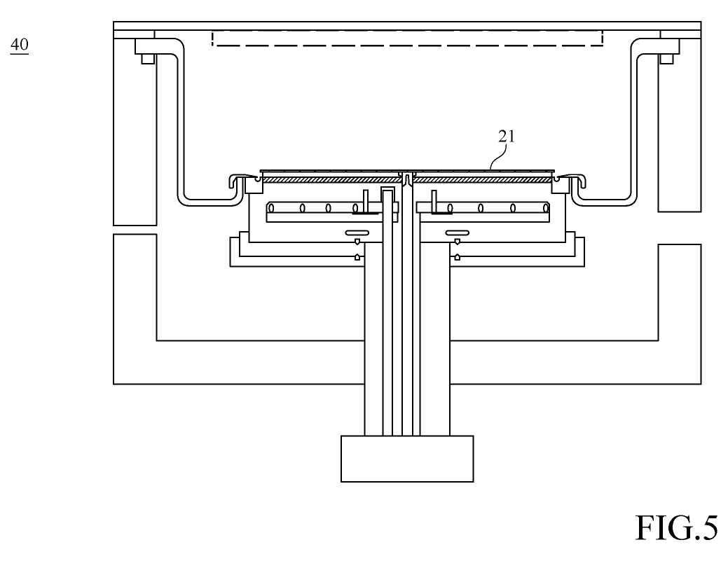

In one embodiment of the invention, the glass substrate 21 may be transported into a deposition chamber 40, as shown in FIG. 5, and the glass substrate 21 can be heated and baked by a heating device of the deposition chamber 40 to remove moisture from the glass substrate 21.

Please referring to FIG. 2, after completing the cleaning process of the glass substrate 21, a titanium metal thin film 22 is deposited on the surface of the glass substrate 21, as shown in step 13.

In one embodiment of the invention, the glass substrate 21 may be transported into a physical vapor deposition (PVD) chamber, and a titanium metal thin film 22 is formed on the surface of the glass substrate 21 by sputtering or evaporation. In different embodiments, the glass substrate 21 may be transported into a chemical vapor deposition (CVD) chamber, a titanium gaseous compound is transported into the CVD chamber, and the titanium gaseous compound is decomposed or reacted at high temperature to produce titanium atoms or titanium molecules, so as to deposit a titanium metal thin film 22 on the surface of the glass substrate 21. In addition, the glass substrate 21 may be transported into an atomic layer deposition (ALD) chamber, and a titanium precursor is transported into the ALD chamber to react with the glass substrate 21. For example, titanium tetrachloride is input into the ALD chamber. Thereafter, a co-reactant is input into the ALD chamber. For example, water or oxygen is input into the ALD chamber, to react with the titanium precursor on the surface of the glass substrate 21, and a titanium metal thin film 22 can be formed on the surface of the glass substrate 21.

It is important to note that the aforementioned deposition techniques are merely illustrative embodiments of the invention and should not be construed as limiting its scope. The utilization of PVD chamber, CVD chamber, and ALD chamber for the formation of the titanium metal thin film 22 on the surface of the glass substrate 21 each presents distinct advantages and disadvantages. Consequently, the selection of an appropriate deposition system for thin film fabrication is contingent upon factors such as the geometric configuration of the glass substrate 21, process quality requirements, and manufacturing cost considerations.

In practical applications, the glass substrate 21 may include a plurality of through holes 211, and the titanium metal thin film 22 is deposited onto both the surface of the glass substrate 21 and the inner surface of the through holes 211.

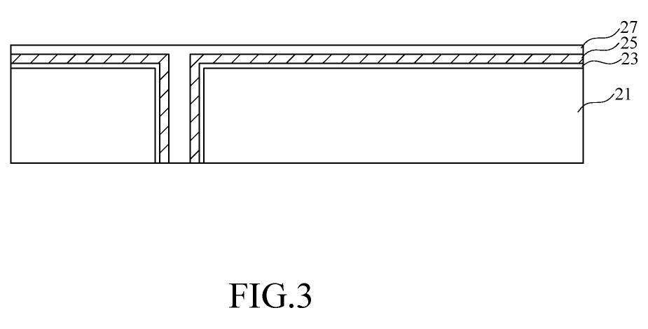

Please referring to FIG. 3, the titanium metal thin film 22 formed on the surface of the glass substrate 21 is performed a surface treatment through a reactive plasma, so that the titanium metal thin film 22 is transformed into an intermediate layer 23, as shown in step 15. The reactive plasma may include oxygen plasma, nitrogen plasma, fluorine plasma, or chlorine plasma, and the intermediate layer 23 is formed on both the surface of the glass substrate 21 and the inner surface of the through holes 211.

In one embodiment of the invention, the titanium metal thin film 22 may be performed the surface treatment with oxygen plasma, wherein the oxygen plasma reacts with the titanium metal thin film 22 and then forms a titanium oxide thin film intermediate layer 23. In alternative embodiments, the titanium metal thin film 22 on the surface of the glass substrate 21 be performed the surface treatment with nitrogen plasma, fluorine plasma, or chlorine plasma, wherein the titanium metal thin film 22 reacts with these plasmas, respectively, forming the intermediate layer 23 of a titanium nitride thin film, a titanium fluoride thin film, or a titanium chloride thin film.

In practical applications, oxygen plasma, nitrogen plasma, fluorine plasma, or chlorine plasma may be generated by a remote plasma source, a capacitively coupled plasma (CCP) source, an inductively coupled plasma (ICP) source, or a microwave plasma source.

Please referring to FIG. 3, a titanium metal conductive layer 25 is deposited on the surface of the intermediate layer 23, as shown in step 17. The titanium metal conductive layer 25 can be formed on the intermediate layer 23, which resides on both the surface of the glass substrate 21 and the inner surface of the through holes 211.

The method for forming the titanium metal conductive layer 25 on the intermediate layer 23 includes PVD, CVD, and ALD. Essentially, the formation method of the titanium metal conductive layer 25 can be similar to the formation method of the titanium metal thin film 22 described in step 13.

Please referring to FIG. 3, in the concluding step, a copper metal conductive layer 27 is deposited on the surface of the titanium metal conductive layer 25, as shown in step 19. The copper metal conductive layer 27 can be formed one the titanium metal conductive layer 25 located above the surface of the glass substrate 21 and the inner surface of the through holes 211. For example, the intermediate layer 23, the titanium metal conductive layer 25, and the copper metal conductive layer 27 can be used to fill the through holes 211 of the glass substrate 21, and the titanium metal conductive layer 25 and the copper metal conductive layer 27 in the through holes 211 are connected to the titanium metal conductive layer 25 and the copper metal conductive layer 27 formed on the surface of the glass substrate 21.

In one embodiment of the invention, the thickness of the intermediate layer 23 may be smaller than the titanium metal conductive layer 25 and/or the copper metal conductive layer 27. For example, the thickness of the intermediate layer 23 may be between 10A and 1000A, or between 500A and 1000A, the thickness of the titanium metal conductive layer 25 may be between 2000A and 2000A, and the thickness of the copper metal conductive layer 27 may be between 2000A and 2000A.

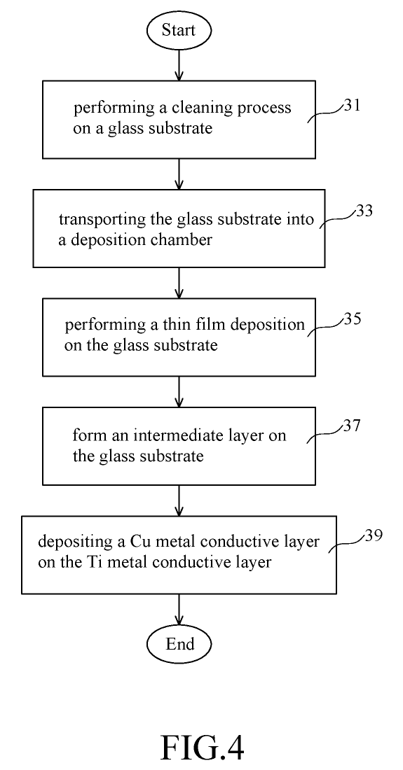

FIG. 4 is a flow chart of the method for depositing the metal conductive layer on the glass substrate according to another embodiment of the invention. Please refer to FIG. 3, the glass substrate 21 is subjected to a cleaning procedure, as shown in step 31.

The method for cleaning the glass substrate 21 mirrors that of step 11 in FIG. 1. For example, acetone is used to clean the glass substrate 21 to remove grease or other organic contaminants from the surface of the glass substrate, then methanol is used to clean the glass substrate 21 to dissolve residual acetone on the surface of the glass substrate 21. Finally deionized water is used to clean the glass substrate 21 to remove residual organic solvents from the surface of the glass substrate 21.

After completing the wet cleaning of the glass substrate 21, the glass substrate 21 can be further heated to remove moisture from the glass substrate 21.

Please referring to FIG. 3 and FIG. 5, subsequent to the completion of the cleaning process for the glass substrate 21, the glass substrate 21 is conveyed into a deposition chamber 40, as delineated in step 33.

In one embodiment of the invention, the glass substrate 21 may be first transported into the deposition chamber 40. Subsequently, the glass substrate 21 undergoes a heating and baking process within the deposition chamber 40, utilizing the heating apparatus of the deposition chamber 40, to eliminate any residual moisture present on the glass substrate 21. In other words, the action of cleaning the glass substrate 21 described in step 31, may exclude the heating process of the glass substrate 21. Instead, the heating process is executed subsequent to step 33.

The deposition chamber 40 described in the above embodiments of the invention may include a PVD chamber, a CVD chamber, or an ALD chamber.

Please referring to FIG. 3, a reactive gas is transported into the deposition chamber 40, and thin film deposition is performed on the surface of the glass substrate 21 in the deposition chamber 40 to form an intermediate layer 23 on the surface of the glass substrate 21. The reactive gas includes oxygen, nitrogen, fluorine, or chlorine, as shown in step 35.

Taking the PVD chamber as an example, an inert gas and a reactive gas can be transported into the PVD chamber. The reactive gas may be oxygen, and the inert gas may be argon. Within the PVD chamber, the argon gas undergoes ionization due to the application of a high-voltage electric field, resulting in the formation of argon ions. These argon ions are subsequently employed to bombard a titanium target located at the cathode, thereby generating titanium atoms or molecules. The titanium atoms or titanium molecules then react with the oxygen in the PVD chamber and deposit on the surface of the glass substrate 21 to form the titanium oxide thin film intermediate layer 23 on the surface of the glass substrate 21.

In different embodiments, the reactive gas may be nitrogen, fluorine, or chlorine, and the intermediate layer 23 formed on the surface of the glass substrate 21 may be a titanium nitride thin film, a titanium fluoride thin film, or a titanium chloride thin film.

Forming the intermediate layer 23 on the surface of the glass substrate 21 through the PVD chamber is merely an embodiment of the invention, and is not a limitation on the scope of the invention. In different embodiments, the deposition chamber 40 may be the CVD chamber, and a titanium gaseous compound and a reactive gas can be transported into the CVD chamber. For example, the titanium gaseous compound may be titanium tetrachloride, wherein titanium tetrachloride is decomposed at a high temperature and reacts with the reactive gas to form the intermediate layer 23 on the surface of the glass substrate 21.

In addition, the deposition chamber 40 may be the ALD chamber, and the titanium precursor and reactive gas may be sequentially transported into the ALD chamber to form the intermediate layer 23 on the surface of the glass substrate 21.

In practical applications, the glass substrate 21 may include a plurality of through holes 211, wherein the intermediate layer 23 can be formed on both the surface of the glass substrate 21 and the inner surface of the through holes 211.

Please referring to FIG. 3, a titanium metal conductive layer 25 is formed on the surface of the intermediate layer 23, as shown in step 37. The titanium metal conductive layer 25 can be formed on the intermediate layer 23, which resides on both the planar surface of the glass substrate 21 and the inner surface of the through holes 211.

The method for forming the titanium metal conductive layer 25 on the intermediate layer 23 includes PVD, CVD, and ALD. Essentially, the formation method of the titanium metal conductive layer 25 can be the same as the formation method of the titanium metal thin film 22 described in step 13 or the formation method described in step 17.

Please referring to FIG. 3, in the concluding step, a copper metal conductive layer 27 is formed on the surface of the titanium metal conductive layer 25, as shown in step 39. The copper metal conductive layer 27 is configured to reside above the surface of the glass substrate 21 and within the inner surface of the through holes 211.

By using the method for depositing the metal conductive layer on the glass substrate 21 as described in the invention, the intermediate layer 23, the titanium metal conductive layer 25, and the copper metal conductive layer 27 can be sequentially formed in the same deposition chamber 40. The formation of the intermediate layer 23 can increase the adhesion between the titanium metal conductive layer 25 and the glass substrate 21. For example, the adhesion between the titanium metal conductive layer 25 and the glass substrate 21 can be increased from 0.05 kgf as described in the prior art to 0.5 kgf, which can greatly reduce the probability of the titanium metal conductive layer 25 falling off the glass substrate 21, and can improve the yield and reliability of subsequent packaging processes.

The foregoing descriptions are merely preferred embodiments of this disclosure, and are not intended to limit the scope of this disclosure, that is, all equivalent changes and modifications made according to shapes, structures, features and spirits described in the scope of the claims of this disclosure shall fall within the scope of the claims of this disclosure.

What is claimed is:

1. A method for depositing a metal conductive layer on a glass substrate, comprising:performing a cleaning process on a glass substrate;depositing a titanium metal thin film on a surface of the glass substrate;performing a surface treatment on the titanium metal thin film located on the surface of the glass substrate through a reactive plasma to transform the titanium metal thin film into an intermediate layer, wherein the reactive plasma includes an oxygen plasma, a nitrogen plasma, a fluorine plasma, or a chlorine plasma, and the intermediate layer includes a titanium oxide thin film, a titanium nitride thin film, a titanium fluoride thin film, or a titanium chloride thin film; anddepositing a titanium metal conductive layer on a surface of the intermediate layer.

2. The method as claim 1, further comprising: depositing a copper metal conductive layer on a surface of the titanium metal conductive layer.

3. The method as claim 2, wherein the glass substrate includes at least one through hole, and the intermediate layer, the titanium metal conductive layer, and the copper metal conductive layer are disposed within the through hole.

4. The method as claim 1, wherein the cleaning process on the glass substrate comprises:
performing wet cleaning on the glass substrate to remove grease or organic contaminants from the surface of the glass substrate; and
heating the glass substrate to remove moisture from the glass substrate.

5. The method as claim 1, wherein the titanium metal thin film, the intermediate layer, and the titanium metal conductive layer are formed on the glass substrate in a chemical vapor deposition chamber, a physical vapor deposition chamber, or an atomic layer deposition chamber.

6. A method for depositing a metal conductive layer on a glass substrate, comprising:performing a cleaning process on a glass substrate;transporting the glass substrate into a deposition chamber;inputting a reactive gas into the deposition chamber, and performing a thin film deposition on the glass substrate to form an intermediate layer on a surface of the glass substrate, wherein the reactive gas includes an oxygen, a nitrogen, a fluorine, or a chlorine, and the intermediate layer includes a titanium oxide thin film, a titanium nitride thin film, a titanium fluoride thin film, or a titanium chloride thin film; and
depositing a titanium metal conductive layer on a surface of the intermediate layer.

7. The method as claim 6, further comprising: depositing a copper metal conductive layer on a surface of the titanium metal conductive layer.

8. The method as claim 6, further comprising: inputting an inert gas and the reactive gas into the deposition chamber.

9. The method as claim 6, the cleaning process on the glass substrate comprises:
performing wet cleaning on the glass substrate to remove grease or organic contaminants from the surface of the glass substrate; and
heating the glass substrate to remove moisture from the glass substrate.

10. The method as claim 6, wherein the deposition chamber includes a chemical vapor deposition chamber, a physical vapor deposition chamber, or an atomic layer deposition chamber.
